(19) United States
(12) Patent Application Publication
(10) Pub. No.: US 2026/0058628 A1
(43) Pub. Date: Feb. 26, 2026

(54) FILTER ASSEMBLY

(71) Applicant: Robert Bosch GmbH, Stuttgart (DE)

(72) Inventors: Christian Haap, Moessingen (DE); Ralf Ziegler, Reutlingen (DE)

(21) Appl. No.: 19/103,644

(22) PCT Filed: Jul. 7, 2023
(86) PCT No.: PCT/EP2023/068883

§ 371 Date: Feb. 13, 2025

(30) Foreign Application Priority Data
Sep. 1, 2022 (DE) 10 2022 209 107.8

(51) Int. Cl. H03H 7/01; H03H 1/00

(52) U.S. Cl. CPC H03H 7/0138; H03H 1/00

(57) ABSTRACT

The invention relates to a filter assembly (40) of an electronic assembly (50) comprising a first bus bar (1), a second bus bar (2), and a capacitor (3), wherein the capacitor (3) is directly connected to each of the two bus bars (1, 2) by means of a material-locking and electrically conductive connection (4).

### BACKGROUND

The present invention relates to a filter assembly of an electronic assembly and an electronic assembly.

Electronic assemblies for power semiconductors in power electronics are known. Capacitors are often used as filters, for example for filtering electromagnetic interference signals. Such capacitors are typically provided as separate components that need to be connected to live components, such as sheets. Known electronic assemblies often have a large number of components and are time consuming and costly to manufacture.

### SUMMARY

The filter assembly according to the invention offers the advantage of a particularly simple and inexpensive design, which allows for particularly simple manufacturing. In addition, it enables a mechanically robust construction and a reliable electrical connection. This is achieved according to the present invention by a filter assembly of an electronic assembly comprising a first bus bar, a second bus bar, and a capacitor. The capacitor is connected directly to each of the two bus bars by means of a material-locking and electrically conductive connection. That is to say, no further components, such as additional welding plates or the like, are arranged between the capacitor and each bus bar.

In particular, a component configured for power transfer in the filter assembly can be considered a bus bar. For example, a separate electrical potential may be provided for each bus bar. In particular, each bus bar is made of an electrically conductive material.

The filter assembly thus offers the advantage of a design having only a few components. In particular, only a single connection between the capacitor and each of the two bus bars is thus required. This can save material and weight on the one hand, for example by omitting additional welding plates, and on the other hand, it can simplify assembly by saving machining steps. Thus, the filter assembly may be provided at a particularly low cost. Furthermore, the filter assembly offers a particularly robust design due to the direct connection of the capacitor to the two bus bars, which can enable, for example, a long service life for the filter assembly. In addition, the direct connection makes it possible to ensure an optimal electrical power transfer between the capacitor and bus bar, for example, because the single connection per bus bar can be manufactured in a simple manner to be of high quality, in order to reliably provide a high-quality connection with optimal electrical properties.

Preferably, the connection between the capacitor and each of the two bus bars is welded connection in every case. This means that a particularly robust connection can be manufactured with ease and in a cost-efficient manner. In addition, optimal electrical conductivity may be ensured for the connection.

Particularly preferably, the connection is a laser welded joint. Thus, the connection can be completed in a particularly precise and time-efficient manner, thereby allowing the filter assembly to be manufactured at low cost with a high-quality connection.

Preferably, each of the two bus bars is designed at least in part, preferably in the area of the connection, as a sheet. That is, a width and/or a length of each bus bar is many times greater than a respective thickness. This makes it possible, for example, to transmit particularly high levels of current with bus bars that can be manufactured in a simple and inexpensive manner. In addition, simple and flexible manufacturing is possible, for example with different complex geometries, in particular due to the ease of shaping the sheet-shaped bus bars.

Preferably, each of the bus bars is made of copper or a copper alloy. A particularly good power transmission as well as an advantageous weldability can thus be provided.

Further preferably, the capacitor on each bus bar comprises a connecting wire connected to the respective bus bar. In particular, a wire-shaped, protruding and electrically conductive area of the capacitor is considered as the connecting wire, which is in particular welded to the bus bar by means of the laser welded joint. Thus, a simple and inexpensive design of the filter assembly can be provided with particularly simple installation.

Preferably, each connecting wire is arranged substantially orthogonal in the area of the connection to a sheet plane of the respective bus bar. In other words, each connecting wire extends along a thickness direction of the respective bus bar within the area in which the connection is disposed. This enables an advantageous and space-saving arrangement of the components of the filter assembly as well as simple installation.

Particularly preferably, each connecting wire contacts a side edge of the respective bus bar. In particular, a front side of the respective bus bar is considered to be a side edge. That is to say, each connecting wire may be placed laterally on each bus bar and welded in that position. This allows for optimum accessibility of the joint for installation, thereby allowing for particularly simple and cost-efficient manufacturing of the filter assembly.

Further, preferably, each of the two bus bars has a fork-shaped connection area that at least partially encompasses the respective connecting wire. In particular, a connection area comprising at least two protruding elements between which the connecting wire can be arranged is considered to be fork-shaped. In particular, each connection area comprises two V-shaped or U-shaped protruding areas between which the respective connecting wire is inserted. A particularly advantageous arrangement and of the connecting wires can thus be provided, along with the ability to connect them in an advantageous manner. In addition, a large contact area between the connecting wire and the bus bar is enabled, whereby an optimal electrical connection can be ensured.

Preferably, the filter assembly is arranged for filtering electromagnetic interference. In particular, the bus bars and the capacitor are designed accordingly to be able to attenuate electromagnetic interference, for example in the area of power electronic components.

Further, the invention relates to an electronic assembly comprising a power electronic component and the described filter assembly. In particular, the power electronic component and the filter assembly are arranged close to one another, preferably integrated into a common component, so that the filter assembly is designed to suppress electromagnetic interference of the electronic assembly. In particular, optimal operation of the power electronic component can thus be enabled.

Preferably, the power electronic component is an inverter, for example a high-voltage drive inverter, a high-voltage DCDC converter, a radiator fan, or another part of an industrial drive, or the like.

### BRIEF DESCRIPTION OF THE DRAWINGS

The invention is described below based on exemplary embodiments in connection with the figures. In the figures, functionally identical components are respectively denoted by identical reference signs. Shown are:

FIG. 1 a perspective view of an electronic assembly according to a preferred exemplary embodiment of the invention,

FIG. 2 a perspective detail view of the electronic assembly in FIG. 1,

FIG. 3 a further detail view of the electronic assembly in FIG. 1, and

FIG. 4 a further detail view of the electronic assembly in FIG. 1.

### DETAILED DESCRIPTION

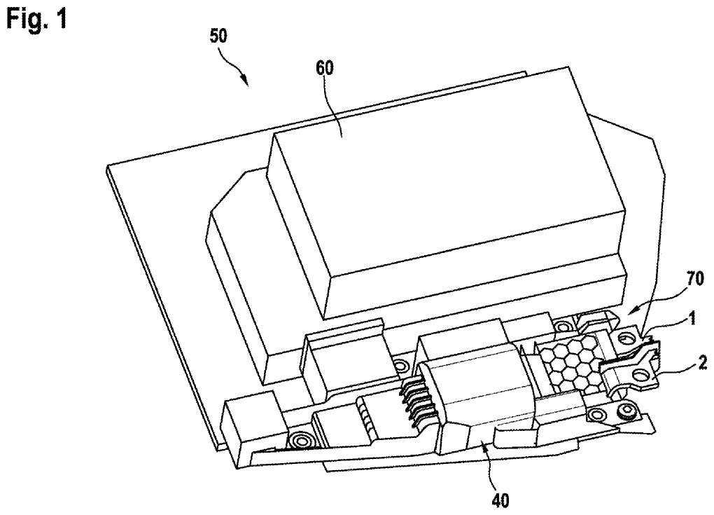

FIG. 1 shows a perspective view of an electronic assembly 50 according to a preferred exemplary embodiment of the invention. The electronic assembly 50 comprises a power electronic component 60, which is in particular configured as an inverter.

The electronic assembly 50 further comprises a filter assembly 40 configured to filter electromagnetic interferences in the electronic assembly 50, in particular in the area of the power electronic component 60.

The power electronic component 60 and the filter assembly 40 are preferably mounted on a common board 70.

The filter assembly 40 includes a first bus bar 1 and a second bus bar 2. The two bus bars 1, 2 each have a different electrical potential.

A capacitor 3, which is a part of the filter assembly 40, is connected to each of the two bus bars 1, 2.

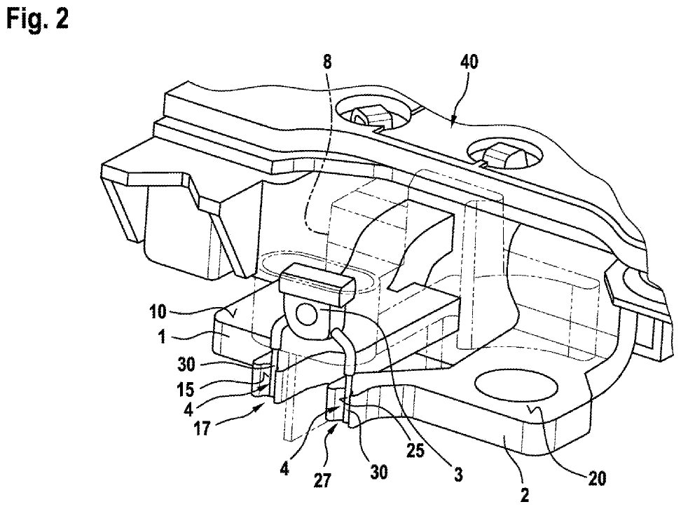

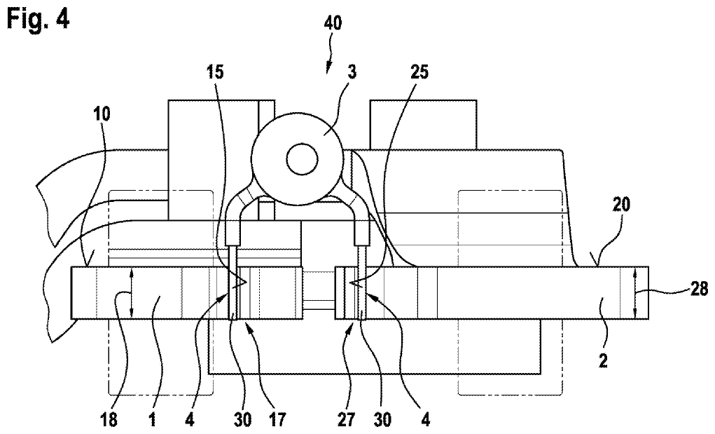

The capacitor 3 is shown in detail in FIGS. 2 to 4 connected to the bus bars 1, 2.

Preferably, the capacitor 3 is a film capacitor or alternatively an electrolytic capacitor.

The capacitor 3 is connected to each of the two bus bars 1, 2 directly by means of a material-locking and electrically conductive connection 4. The connection 4 is a laser welded joint.

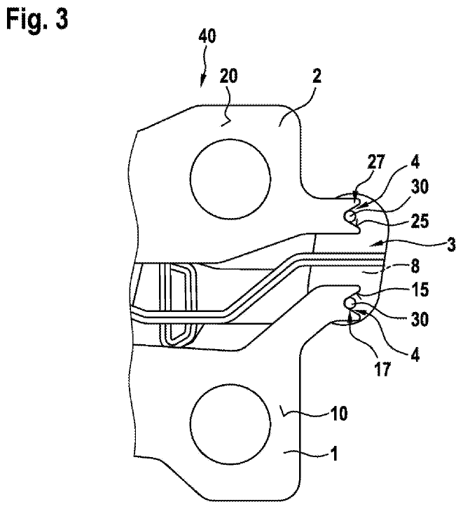

Preferably, as can be seen in FIGS. 2 and 3, the capacitor 3 is integrated into a holding area 8 in the mounted state of the filter assembly 40. The holding area 8 can be, for example, a plastic or the like, in which the capacitor 3 is cast, for example, to provide a stable mechanical bracket for the capacitor 3.

The two bus bars 1, 2 are each formed as a sheet, and in particular are formed from copper or a copper alloy. Thus, a high flexibility in the geometry of the bus bar 1, 2 can be provided, for example, because they are easily deformable, along with the ability for the bus bars to be manufactured simply and inexpensively. For example, the two bus bars 1, 2 can have separate areas on different planes to enable optimal space-saving arrangements.

Each bus bar 1, 2 has a predetermined thickness 18, 28, which is preferably constant over the respective entire bus bar 1, 2, for example, the predetermined thickness 18, 28 is at least several millimeters, preferably 4 mm.

The capacitor 3 further comprises two connecting wires 30 by means of which the material-locking and electrically conductive connection 4 is formed with the two bus bar bars 1, 2. That is, the laser welded joint is formed between each connecting wire 30 and the respective bus bar 1, 2.

Each bus bar 1, 2 comprises a connection area 17, 27, at which the respective laser welded joint is formed with the respective connecting wire 30 of the capacitor 3.

The respective connecting wire 30 is arranged orthogonally to a sheet plane 10, 20 of the respective bus bar 1, 2 at the connection 4.

The connection areas 17, 27 of each bus bar bar 1, 2 are fork shaped, as can be seen in particular in FIG. 3, which shows a top view of a detail of the filter assembly 40, wherein the drawing plane is parallel to the sheet planes 10, 20.

As can be seen in FIG. 3, each fork-shaped connection area 17, 27 comprises a V-shaped recess at its end, into each of which a connecting wire 30 is inserted. Each connecting wire 30 is thus in contact with a side edge 15, 25 of the respective bus bar 1, 2. In particular, a side surface of the sheet-shaped bus bar 1, 2 arranged orthogonally to the respective sheet plane 10, 20 is considered a side edge. Thus, each connecting wire 30 is at least partially encompassed by the respective fork-shaped connection area 17, 27 of the respective bus bar 1, 2.

On the one hand, this makes it possible to provide a precisely positioned arrangement of the connecting wires 30 in a particularly simple manner. On the other hand, a large contact area between the bus bar 1, 2 and connecting wire 30 can be enabled as the bus bar 1, 2 and connecting wire 30 contact around a larger sub-area of a peripheral surface of the connecting wire 30. In addition, a laser welded joint with a larger area can be provided by the thus increased contact area, whereby an optimal electrical connection can be provided in addition to a particularly stable mechanical connection.

1. A filter assembly of an electronic assembly (50), comprising:
a first bus bar (1),
a second bus bar (2), and
a capacitor (3),
wherein the capacitor (3) is directly connected to each of the two bus bars (1, 2) by a material-locking and electrically conductive connection (4).

2. A filter assembly according to claim 1, wherein the connection (4) is a welded joint.

3. A filter assembly according to claim 2, wherein the connection (4) is a laser welded joint.

4. A filter assembly according to claim 1, wherein each bus bar (1, 2) is configured as a sheet at least in an area of the connection (4).

5. A filter assembly according to claim 4, wherein the capacitor (3) comprises one connecting wire (30) per bus bar (1, 2), each of which is connected to the respective bus bar (1, 2).

6. A filter assembly according to claim 5, wherein each connecting wire (30) extends in the area of the connection (4) substantially orthogonally to a sheet plane (10, 20) of the respective bus bar (1, 2).

7. A filter assembly according to claim 5, wherein each connecting wire (30) is in contact with a side edge (15, 25) of the respective bus bar (1, 2).

8. A filter assembly according to claim 5, wherein each bus bar (1, 2) has a fork-shaped connection area (17, 27) at least partially encompassing the respective connecting wire (30).

9. A filter assembly according to claim 1, wherein the filter assembly (40) is configured to filter electromagnetic interference.

10. An electronic assembly comprising:
a power electronic component (60), and
a filter assembly (40) according to claim 1.

11. The electronic assembly of claim 10, wherein the power electronic component (60) is an inverter.
